(19) United States
(12) Patent Application Publication
(10) Pub. No.: US 2023/0137599 A1
(43) Pub. Date: May 4, 2023

(54) SURFACE TREATMENT OF SOI WAFER

(71) Applicants: Zing Semiconductor Corporation, Shanghai (CN); Shanghai Institute of Microsystem and Information Technology, Chinese Academy of Sciences, Shanghai (CN)

(72) Inventors: Xing WEI, Shanghai (CN); Rongwang DAI, Shanghai (CN); Ziwen WANG, Shanghai (CN); Minghao LI, Shanghai (CN); Hongtao XU, Shanghai (CN); Meng CHEN, Shanghai (CN)

(73) Assignees: Zing Semiconductor Corporation, Shanghai (CN); Shanghai Institute of Microsystem and Information Technology, Chinese Academy of Sciences, Shanghai (CN)

(21) Appl. No.: 17/586,046

(22) Filed: Jan. 27, 2022

(30) Foreign Application Priority Data
Oct. 29, 2021 (CN) 202111276158.8

(51) Int. Cl. H01L 21/324; C30B 29/06; H01L 29/06

(52) U.S. Cl. CPC H01L 21/324; C30B 29/06; H01L 29/0684

(57) ABSTRACT

The present application provides a method of surface treatment of a SOI wafer comprising: providing a SOI wafer comprising a substrate, atop silicon layer and an insulating buried layer, wherein the insulating buried layer is located between the back substrate and the top silicon layer, and the top silicon layer has a surface roughness of larger than 10 Å; removing a native oxide layer from a surface of the top silicon layer by conducting a first isothermal annealing process at a first target temperature, wherein the first isothermal annealing process is under atmosphere of a mixture of argon and hydrogen; and planarizing the surface of the top silicon layer by conducting a second isothermal annealing process at a second target temperature, wherein the second target temperature is higher than the first target temperature, and the second isothermal annealing process is under atmosphere of argon. The present method can optimize the atmosphere for batch annealing to achieve better planarization than the conventional technologies. Specifically, the obtained top silicon layer of the SOI wafer has a surface roughness of less than 4 Å.

### BACKGROUND OF THE INVENTION

### 1. Field of the Invention

The present invention relates to semiconductor manufacture, and more particularly to surface treatment of SOI wafer.

### 2. Description of the Related Art

With the development of post-Moore period, the requests for structure, thickness uniformity and the surface flatness of silicon-on-insulator (SOI) become more strict. Currently, SOI can be broadly applied in the technical fields of microelectronics, optics and optoelectronics, but the challenges for SOI materials increases correspondingly. In SOI, at least one layer of buried oxidation layer is introduced between atop silicon layer and a back substrate. It is requested that an advanced SOI device has atop silicon layer as thinner as possible. However, chemical mechanical polishing (CMP) conventionally applied to thinning and planarization processes causes non-uniform thickness of the top silicon layer, resulting in introduction of additional surface defects.

To solve the above problems in planarization, a thermal annealing treatment is applied to replace the conventional CMP to planarize the surface of the top silicon layer. The thermal annealing treatment includes the batch annealing treatment and the rapid thermal annealing treatment. Advantages of the batch annealing includes that the wafer is planarized by reduce the relative height of long-term fluctuations of the wafer surface topography during a long time period, while advantages of the rapid thermal annealing includes that the wafer is planarized by reduce the relative height of short-term fluctuations of the wafer surface topography during a short time period. Surface roughness of the SOI is the main evaluation standard of thermal annealing process because it significantly affects the performance of back-end device. Conventionally, the thermal annealing process for SOI is conducted under atmosphere of a mixture of argon and hydrogen, wherein hydrogen is mainly to prevent the existence of oxygen or/and oxide. The oxygen and oxide during whole anneal process causes deteriorated granulation on the surface of the top silicon layer. However, the silicon surface is etched by hydrogen at high temperature. For example, U.S. Pat. No. 9,202,711 B2 discloses a batch annealing treatment under atmosphere of a mixture of argon and hydrogen for planarization of SOI. The treatment reduces surface point defects and surface roughness of wafer with a certain degree, but it ignores the negative effects of hydrogen. The prior art fails to optimize the hydrogen.

### SUMMARY

The purpose of the present application is to provide a method of surface treatment of SOI (silicon-on-insulator) wafer to eliminate the negative effect to the SOI wafer caused by hydrogen during the batch annealing treatment, and optimize the wafer processing procedure and the wafer surface roughness.

For the above purpose, the present application provides a method of surface treatment of a SOI wafer comprising:
providing a SOI wafer comprising a substrate, atop silicon layer and an insulating buried layer, wherein the insulating buried layer is located between the back substrate and the top silicon layer, and the top silicon layer has a surface roughness of larger than 10 Å;
removing a native oxide layer from a surface of the top silicon layer by conducting a first isothermal annealing process at a first target temperature, wherein the first isothermal annealing process is under atmosphere of a mixture of argon and hydrogen; and
planarizing the surface of the top silicon layer by conducting a second isothermal annealing process at a second target temperature, wherein the second target temperature is higher than the first target temperature, and the second isothermal annealing process is under atmosphere of argon.

In one embodiment, the mixture of argon and hydrogen comprises less than 10% of hydrogen.

In one preferred embodiment, the mixture of argon and hydrogen comprises less than 3% of hydrogen.

In one embodiment, the first isothermal annealing process is conducted at 900° C.-1150° C. for less than 10 min; and the second isothermal annealing is conducted at 1100° C.-1250° C. for 10 min-120 min.

In one preferred embodiment, the first isothermal annealing process is conducted at 1100° C. for 5 min; and the second isothermal annealing process is conducted at 1200° C. for 30 min-60 min.

In one embodiment, the first isothermal annealing process comprises:
loading the SOI wafer into a vertical tubular furnace under atmosphere of argon;
conducting a first heating-up period under atmosphere of a mixture of argon and hydrogen; and
conducting the first isothermal annealing process to remove the native oxide layer from the surface of the top silicon layer while the first target temperature is reached by the first heating-up period, wherein the atmosphere for the first isothermal annealing process is maintained as a mixture of argon and hydrogen.

In one embodiment, the second isothermal annealing process comprises:
conducting a second heating-up period under atmosphere of argon; and
conducting the second isothermal annealing process to planarize the surface of the top silicon layer while the second target temperature is reached by the second heating-up period, wherein the atmosphere for the second isothermal annealing process is maintained as argon.

In one embodiment, the method further comprises:
after the second isothermal annealing process, growing a silicon oxide film on the surface of the top silicon layer by conducting a thermal oxidation process at a third target temperature, wherein the third target temperature is lower than the second target temperature, and thermal oxidation process is under atmosphere of oxygen; and
removing the silicon oxide film by wet etching to thinning the top silicon layer.

In one embodiment, the third target temperature is 800° C.-1000° C.

In one preferred embodiment, the third target temperature is 900° C.-950° C.

The present application also provides a silicon-on-insulator (SOI) wafer having a surface roughness of less than 4 Å. Top silicon layer of the SOI wafer has an excellent thickness uniformity, e.g. the variation of the thickness of top silicon layer being ±1%. The SOI wafer can be manufactured by the method described above.

Compared with the conventional technologies, the present application provides the following advantages.

The present application provides a method of surface treatment of a SOI wafer comprising: providing a SOI wafer comprising a back substrate, atop silicon layer and an insulating buried layer, wherein the insulating buried layer is located between the back substrate and the top silicon layer, and the top silicon layer has a surface roughness of larger than 10 Å; removing a native oxide layer from a surface of the top silicon layer by conducting a first isothermal annealing process at a first target temperature, wherein the first isothermal annealing process is under atmosphere of a mixture of argon and hydrogen; and planarizing the surface of the top silicon layer by conducting a second isothermal annealing process at a second target temperature, wherein the second target temperature is higher than the first target temperature, and the second isothermal annealing process is under atmosphere of argon. The present method is able to optimize the atmosphere for batch annealing to achieve better planarization than the conventional technologies. Specifically, the present method can provide the obtained SOI wafer having top silicon layer with a surface roughness of less than 4 Å.

The present application further provides two cooling steps and a third isothermal step between the two cooling steps. In the third isothermal step, a silicon oxide film is grown on the surface of the top silicon layer opposite to an insulating layer. Accordingly, the thermal oxidation treatment in the conventional thinning process is adjusted to be incorporated into the planarization process of SOI wafer, so that the process can be simplified and the cost can be reduced.

### BRIEF DESCRIPTION OF THE DRAWINGS

FIG. 1 is a flowchart illustrating method steps for surface treatment of SOI wafer.

FIG. 2 shows a sectional view of a SOI wafer according to Example 1 of the present application.

FIG. 3 is a temperature-time diagram of the thermal annealing process according to Example 1 of the present application.

FIG. 4 is a temperature-time diagram of the thermal annealing process combined with the thinning process according to Example 2 of the present application.

### DETAILED DESCRIPTION OF THE EMBODIMENTS

To fully understand the present application, detailed structures or steps of the method for surface treatment of the SOI wafer are set forth in the following descriptions to explain the technical solutions of the present application. The implementation of the present application is not limited by the specific detail known by a person having ordinary skills in the art. The preferred embodiments of the present application are described in detail below, but the present application may have other embodiments in addition to the detailed description.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

For easy understanding of the purpose and features of the present invention, the embodiments of the present invention will be further described below with reference to the accompanying drawings. It should be specified that the drawings are provided with very simplified form and imprecise ratios for convenient and clear assistance in explaining the embodiments.

### EXAMPLES

### Example 1

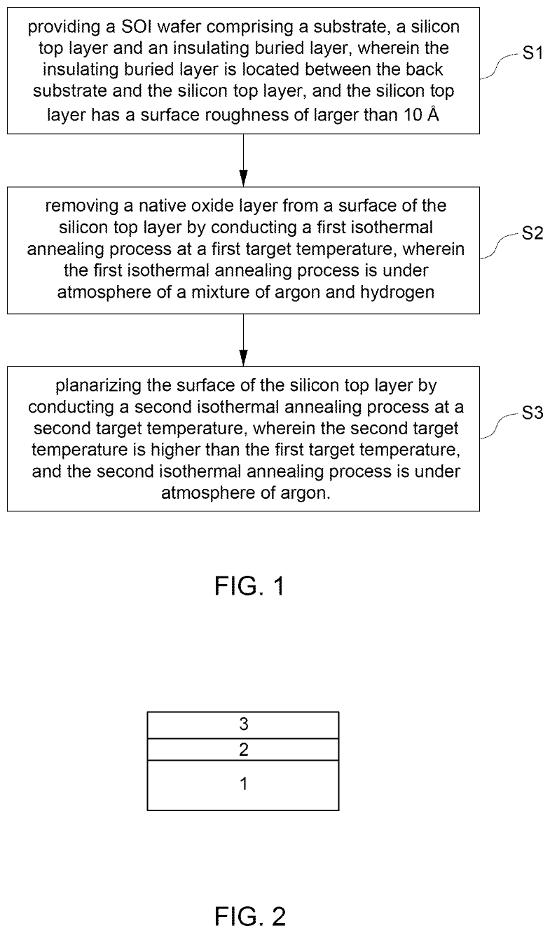

FIG. 1 is a flowchart illustrating method steps for surface treatment of SOI wafer. As shown in FIG. 1, the method of surface treatment of a SOI wafer provided in Example 1 comprises the following steps.

Step S1: providing a SOI wafer comprising a substrate, atop silicon layer and an insulating buried layer, wherein the insulating buried layer is located between the back substrate and the top silicon layer, and the top silicon layer has a surface roughness of larger than 10 Å;

Step S2: removing a native oxide layer from a surface of the top silicon layer by conducting a first isothermal annealing process at a first target temperature, wherein the first isothermal annealing process is under atmosphere of a mixture of argon and hydrogen; and

Step S3: planarizing the surface of the top silicon layer by conducting a second isothermal annealing process at a second target temperature, wherein the second target temperature is higher than the first target temperature, and the second isothermal annealing process is under atmosphere of argon.

Referring FIG. 1-FIG. 3, the method of surface treatment of a SOI wafer is further described as follows.

FIG. 2 shows a sectional view of a SOI wafer of this example. As shown in FIG. 2, the step 51 is conducted to provide a SOI wafer. The SOI wafer comprising a back substrate 1, atop silicon layer 3 and an insulating buried layer 2, wherein the insulating buried layer 2 is located between the back substrate 1 and the top silicon layer 3, and the top silicon layer 3 has a surface roughness of larger than 10 Å

Specifically, the step 51 comprises the following steps.

First, a bonding structure is provided. The bonding structure comprises an initial top silicon layer, an insulating buried layer 2 and a back substrate 1, wherein the insulating buried layer 2 is located between the initial top silicon layer and the back substrate 1. A damage layer is formed in the initial top silicon layer.

The surface of the initial top silicon layer opposite to the insulating buried layer 2 is subjected to an initial annealing process, so that the bonding structure can be peeled from and along with the damage layer. The SOI wafer is obtained.

However, the surface of the initial top silicon layer opposite to the insulating buried layer 2 has a surface roughness larger than 10 Å because of the peel-off process.

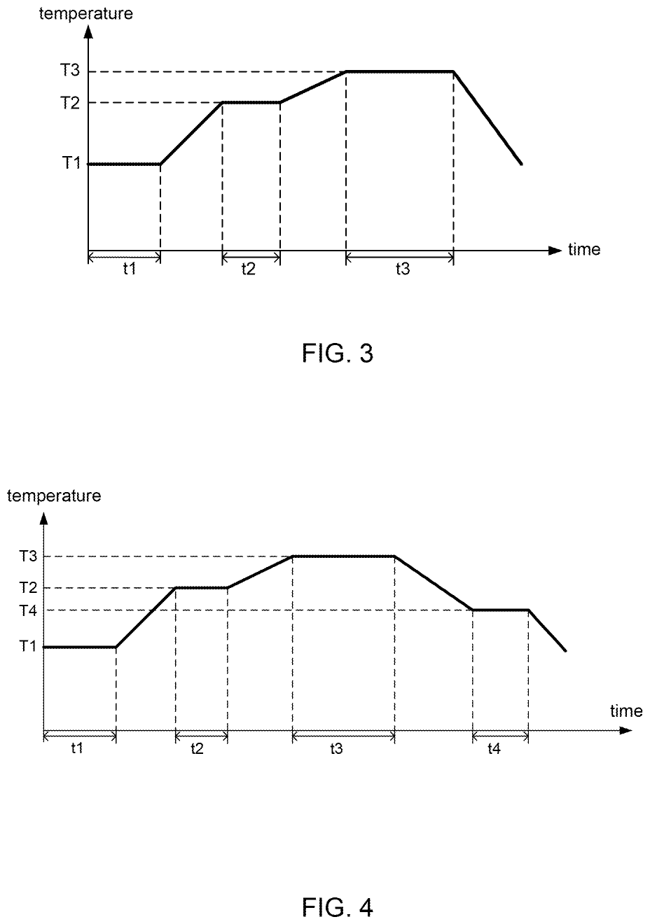

FIG. 3 is a temperature-time diagram of the thermal annealing process according to Example 1 of the present application. Referring FIG. 3, the step S2 is conducted. A native oxide layer is removed from a surface of the top silicon layer 3 by a first isothermal annealing process at a first target temperature. The first isothermal annealing process is under atmosphere of a mixture of argon and hydrogen.

Specifically, the following steps are included.

First, the SOI wafer is loaded into a vertical tubular furnace. The loading temperature T1 is 500° C.-800° C., and the preferable T1 is 650° C. The time period t1 for maintenance of the loading temperature is 1 mM-10 min, and the preferable t1 is 5 min The loading atmosphere is argon only, i.e. pure argon.

Then, a first heating-up period is initiated. At the same time, the atmosphere is switched from pure argon to a mixture of argon and hydrogen. The gas mixture comprises less than 10% of hydrogen, and preferably less than 3% of hydrogen.

The first heating-up period has a heating rate of 0.5° C./min-20° C./min, and preferably 5° C./min-7° C./min.

While the first target temperature T2 is reached in the first heating-up period, a first isothermal stage, i.e. a first stable maintenance stage of temperature, is started. The atmosphere of the first isothermal stage is still the mixture of argon and hydrogen. The first target temperature T2 is 900° C.-1150° C., and preferably 1100° C. The time period t2 for maintenance of the first isothermal stage is less than 10 min, and preferably 5 min. In this step, in the first isothermal stage, the native oxide layer naturally formed on the surface of the top silicon layer 3 can be removed by hydrogen at the first target temperature T2. In this step, the concentration of hydrogen in the gas mixture is optimized, namely, the hydrogen is less than 10%, which is able to remove the native oxide layer from the top silicon layer 3 in a short period of time, eliminate the passivation in the thermal annealing process caused by hydrogen, and initially reduce the surface roughness of the top silicon layer 3.

Continuously referring FIG. 1, the step S3 is conducted. Heating is conducted to reach a second target temperature from the first target temperature. At the second target temperature, the surface of the top silicon layer is planarized by conducting a second isothermal annealing process. The second isothermal annealing process is under atmosphere of argon, i.e. pure argon. In this step, the second target temperature is higher than the first target temperature for the further planarization to the surface of the top silicon layer.

Specifically, the following steps are included in the second isothermal annealing process.

A second heating-up period is initiated. At the same time, the atmosphere is switched to pure argon. While the second target temperature T3 is reached in the second heating-up period, a second isothermal stage, i.e. a second stable maintenance stage of temperature, is started.

The atmosphere of the second isothermal stage is maintained as pure argon. The second target temperature T3 is 1100° C.-1250° C., and preferably 1200° C. The time period t3 for maintenance of the second isothermal stage is 10 min-120 min, and preferably 30 min-60 min.

In this example, the conventional batch annealing treatment is not continuously applied. However, the conventional temperature increase step is separated to two steps, i.e. the first heating-up period and the second heating-up period, respectively, as described above. In addition, the first isothermal stage is added between the first heating-up period and the second heating-up period. The planarization is conducted to the surface of the top silicon layer via the two isothermal stages at different temperature and under different atmospheres. Namely, the first isothermal stage under atmosphere of the mixture of argon and hydrogen, and the second isothermal stage under atmosphere of pure argon are applied for the two-step planarization of the surface of the top silicon layer. In this example, the atmosphere used in the batch annealing process is optimized, resulting the better planarization than that of conventional technologies. Specifically, the obtained top silicon layer of the SOI wafer has a surface roughness of less than 4 Å.

Referring FIG. 3, the following steps are conducted after the step S3.

While the atmosphere of pure argon is maintained, a cooling step is initiated. The cooling rate is 1° C./min-10° C. /min, and preferably 3° C./min-5° C./min

The cooling step is conducted until the temperature is decreased to the device temperature, i.e. 500° C.-800° C., to complete the surface treatment of the SOI wafer.

Optionally, the SOI wafer is subjected to an additional annealing process to form a silicon oxide film on the surface of the top silicon layer under atmosphere of oxygen. Then, the silicon oxide film can be removed by wet etching to thinning the SOI wafer.

### Example 2

In this example, the steps S1-S3 described in Example 1 are conducted, but the following steps are further conducted after the step S3.

FIG. 4 is a temperature-time diagram of the thermal annealing process combined with the thinning process according to this example. Referring FIG. 4, a cooling step is initiated while the atmosphere of pure argon is maintained. The cooling rate is 0.5° C./min-10° C./min, and preferably 0.5° C./min-5° C./min.

Also referring FIG. 2, while the third target temperature T4 is reached in a first cooling step, a third isothermal stage, i.e. a third stable maintenance stage of temperature, is started. At this time, the atmosphere is switched to oxygen to conduct a thermal oxidation process to grow a silicon oxide film on the surface of the top silicon layer 3 opposite to the insulating buried layer 2. The atmosphere of oxygen can be dry oxygen, wet oxygen, or a mixture thereof. The third target temperature T4 is 800° C.-1000° C., and preferably 900° C.-950° C. . The time period t4 for maintenance of the third isothermal stage depends on the desired thickness of the formed top silicon layer. In this example, the thermal oxidation treatment in the conventional thinning process is adjusted to be incorporated into the planarization process of SOI wafer, so that the process can be simplified and the cost can be reduced.

A second cooling step is initiated while the atmosphere is switched to pure argon. The cooling rate of the second cooling step is 1° C./min-10° C./min, and preferably 3° C./min-5° C./min The cooling step is conducted until the temperature is decreased to the device temperature, i.e. 500° C.-800° C., and preferably 650° C. .

Then, the silicon oxide film is removed by wet etching, thereby the thinning process of the top silicon layer can be completed. The wet etching can be conducted in a solution of hydrogen fluoride (HF). The concentration of HF is less than 20%, and the preferable HF concentration is 5%.

According to the above, the conventional batch annealing treatment is not continuously applied. However, the conventional temperature increase step is separated to two steps, i.e. the first heating-up period and the second heating-up period, respectively, as described above. In addition, the first isothermal stage is added between the first heating-up period and the second heating-up period. The planarization is conducted to the surface of the top silicon layer via the two isothermal stages at different temperature and under different atmospheres. Namely, the first isothermal stage under atmosphere of the mixture of argon and hydrogen, and the second isothermal stage under atmosphere of pure argon are applied for the two-step planarization of the surface of the top silicon layer. Accordingly, the atmosphere used in the batch annealing process is optimized, resulting the better planarization than that of conventional technologies. Specifically, the obtained top silicon layer of the SOI wafer has a surface roughness of less than 4 Å.

Further, the present application optionally provides the two-stage cooling process and the third isothermal stage between the two cooling steps. In the third isothermal stage, the silicon oxide film is formed on the surface of the top silicon layer opposite to the insulating layer, such that the thermal oxidation treatment in the conventional thinning process is adjusted to be incorporated into the planarization process of SOI wafer. Accordingly, the process can be simplified and the cost can be reduced.

It should be noted that, unless otherwise specified or indicated, the description of the terms “first”, “second”, and “third” in the specification are only used to distinguish each component, element, step and the like in the specification, but not to indicate the logical relationship or sequence relationship between these components, elements, steps and the like.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims and its equivalent systems and methods.

What is claimed is:

1. A method of surface treatment of a silicon-on-insulator (SOI) wafer comprising:
providing a SOI wafer comprising a back substrate, atop silicon layer and an insulating buried layer, wherein the insulating buried layer is located between the back substrate and the top silicon layer, and the top silicon layer has a surface roughness of larger than 10 Å;
removing a native oxide layer from a surface of the top silicon layer by conducting a first isothermal annealing process at a first target temperature, wherein the first isothermal annealing process is under atmosphere of a mixture of argon and hydrogen; and
planarizing the surface of the top silicon layer by conducting a second isothermal annealing process at a second target temperature, wherein the second target temperature is higher than the first target temperature, and the second isothermal annealing process is under atmosphere of argon.

2. The method of claim 1, wherein the mixture of argon and hydrogen comprises less than 10% of hydrogen.

3. The method of claim 2, wherein the mixture of argon and hydrogen comprises less than 3% of hydrogen.

4. The method of claim 1, wherein the first isothermal annealing process is conducted at 900° C.-1150° C. for less than 10 min; and the second isothermal annealing is conducted at 1100° C.-1250° C. for 10 min-120 min.

5. The method of claim 4, wherein the first isothermal annealing process is conducted at 1100° C. for 5 min; and the second isothermal annealing process is conducted at 1200° C. for 30 min-60 min.

6. The method of claim 1, wherein the first isothermal annealing process comprises:
loading the SOI wafer into a batch vertical furnace under atmosphere of argon;
conducting a first heating-up period under atmosphere of a mixture of argon and hydrogen; and
conducting the first isothermal annealing process to remove the native oxide layer from the surface of the top silicon layer while the first target temperature is reached by the first increase of temperature, wherein the atmosphere for the first isothermal annealing process is maintained as a mixture of argon and hydrogen.

7. The method of claim 1, wherein the second isothermal annealing process comprises:
conducting a second heating-up period under atmosphere of argon; and
conducting the second isothermal annealing process to planarize the surface of the top silicon layer while the second target temperature is reached by the second heating-up period, wherein the atmosphere for the second isothermal annealing process is maintained as argon.

8. The method of claim 1, further comprises:
after the second isothermal annealing process, growing a silicon oxide film on the surface of the top silicon layer by conducting a thermal oxidation process at a third target temperature, wherein the third target temperature is lower than the second target temperature, and thermal oxidation process is under atmosphere of oxygen; and
removing the silicon oxide film by wet etching to thinning the top silicon layer.

9. The method of claim 8, wherein the third target temperature is 800° C.-1000° C.

10. The method of claim 9, wherein the third target temperature is 900° C.-950° C.

11. A silicon-on-insulator (SOI) wafer having a surface roughness of less than 4 Å and a thickness uniformity of top silicon layer with variation of ±1%.
